(19) United States
(12) Patent Application Publication
(10) Pub. No.: US 2007/0002548 A1
(43) Pub. Date: Jan. 4, 2007

(54) Pulling assembly for electronic module

(75) Inventors: Hung-Chun Lu, Tu-Cheng (TW); Qi-Fei Fan, Shenzhen (CN); Wen-Kang Lo, Tu-Cheng (TW); Xiao-Gang Jiang, Shenzhen (CN); Chien-Li Tsai, Tu-Cheng (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/479,496

(22) Filed: Jun. 30, 2006

(30) Foreign Application Priority Data
Jul. 1, 2005 (CN) 200520061102.0

(51) Int. Cl. H05K 5/00

(52) U.S. Cl. 361/754

(57) ABSTRACT

A pulling assembly is provided for pulling an electronic module out of a computer enclosure. The pulling assembly includes an installing portion, a pulling member and an manipulating section. The installing portion is formed on the computer enclosure. The pulling member is slidably arranged in the computer enclosure by the installing portion. The manipulating section pivotally connected to the pulling member. The manipulating section drives the pulling member to slide along the installing portion and the pulling member pulls the electronic module to slide a certain distance to facilitate the electronic module being taken out from the computer enclosure.

### BACKGROUND OF THE INVENTION

1. Field of the Invention

The present invention relates to pulling assembly for electronic modules, and particularly to a pulling assembly for readily pulling an electronic module out of a computer enclosure.

2. General Background

The production of notebook computer has become mature and entered a meager profit era. Only cost down and bringing convenience to users can bring more competitive strength. Typically, electronic modules, such as hard disk drives (HDDs), and compact disk-read only memory (CD-ROM) drives, are attached to a bottom panel of a notebook computer enclosure. A connector of an electronic module connects with a connector of a motherboard in the notebook computer to exchange data. However, because the interior space of the notebook computer enclosure is very limited, some elements besides the electronic module must be detached in order to achieve operating space for pulling out the connector of the electronic modules from the connector of the motherboard. The process of detaching an electronic module is very inconvenient.

What is needed is a pulling assembly for readily pulling an electronic module out of a computer enclosure.

### SUMMARY

In one preferred embodiment, a pulling assembly is provided for pulling an electronic module out of a computer enclosure. The pulling assembly includes an installing portion, a pulling member and a manipulating section. The installing portion is formed on the computer enclosure. The pulling member is slidably arranged in the computer enclosure by the installing portion. The manipulating section pivotally connected to the pulling member. The manipulating section drives the pulling member to slide along the installing portion and the pulling member pulls the electronic module to slide a certain distance to facilitate the electronic module being taken out from the computer enclosure.

Other advantages and novel features will become more apparent from the following detailed description when taken in conjunction with the accompanying drawings, in which:

### BRIEF DESCRIPTION OF THE DRAWINGS

FIG. 1 is an exploded, isometric view of a pulling assembly with a pulling member in accordance with a first embodiment of the present invention, together with an electronic module, a mounting apparatus and a notebook computer enclosure;

FIG. 2 is an enlarged view of the pulling member;

FIG. 3 is an assembled view of FIG. 1, showing the electronic module being locked;

FIG. 4 is an inverted view of FIG. 3;

FIG. 5 is an assembled view of FIG. 1, showing the electronic module being pulled out;

FIG. 6 is an inverted view of FIG. 5;

FIG. 7 is an enlarged view of the pulling member in accordance with a second embodiment of the present invention;

FIG. 8 is an assembled view of the pulling assembly in accordance with a second embodiment of the present invention, showing the electronic module being locked; and

FIG. 9 is an assembled view of the pulling assembly in accordance with a second embodiment of the present invention, showing the electronic module being pulled out.

### DETAILED DESCRIPTION OF THE EMBODIMENTS

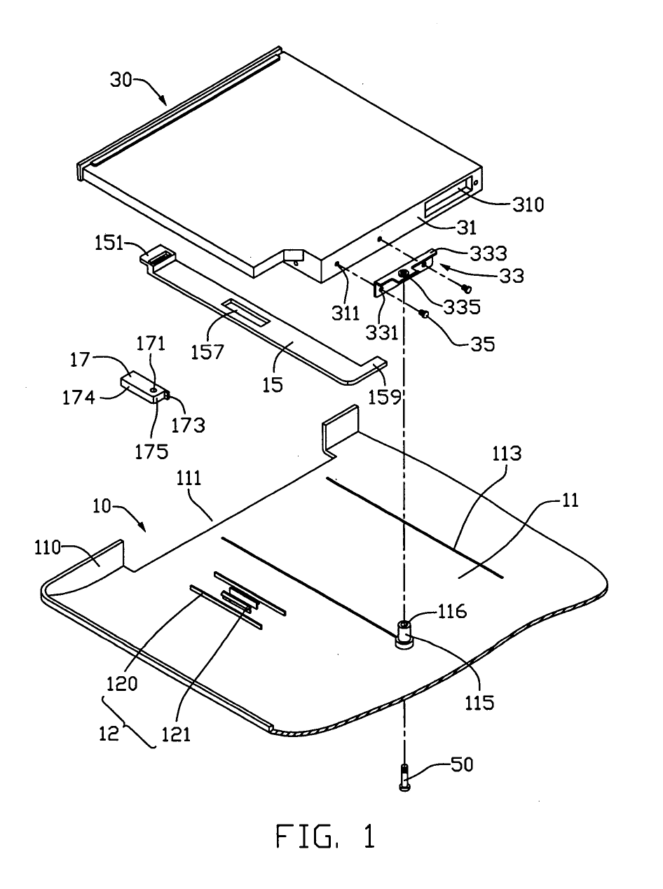

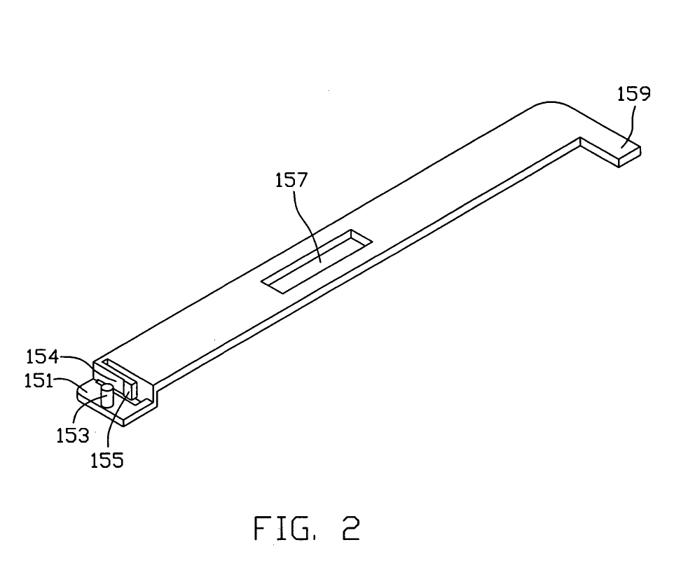

Referring to FIGS. 1 and 2, a pulling assembly in accordance with a first embodiment of the present invention is provided to pull an electronic module 30 out of an enclosure 10 of an electronic device like a notebook computer. The electronic module 30 is a data storage device in this embodiment. The notebook computer enclosure 10 includes a bottom panel 11 and a side panel 110. An opening 111 is defined in the side panel 110 for entry of the electronic module 30. A plurality of sliding rails 113 is formed on the bottom panel 11 to reduce friction when the electronic module 30 slides into or out of the notebook computer enclosure 10. A rear wall 31 of the electronic module 30 includes a connector 310.

The electronic module 30 is attached to the notebook computer enclosure 10 by a mounting apparatus. The mounting apparatus includes a positioning post 115, a fixing plate 33 and a screw 50. The positioning post 115 protrudes from the bottom panel 11, and a round hole 116 is defined in the positioning post 115. A pair of through holes 331 is defined in the body of the fixing plate 33. A pair of threaded holes 311 is defined in the rear wall 31 of the electronic module 30. A pair of screws 35 extends through the through holes 331 then engages in the threaded holes 311 respectively, thus the fixing plate 33 is mounted to the rear wall 31 of the electronic module 30. The fixing plate 33 includes a bent portion 333 with a securing hole 335. The screw 50 extends through the round hole 116 of the positioning post 115 then engages in the securing hole 335 of the fixing plate 33, thus the electronic module 30 is attached to the notebook computer enclosure 10.

The pulling assembly includes an installing portion 12, a pulling member 15, and a manipulating section 17.

The installing portion 12 is formed on an inner side of the bottom panel 11 of the notebook computer enclosure 10. The installing portion 12 includes a pair of guide rails 120 and a pair of clasps 121. The guide rails 120 run parallel to each other, and the clasps 121 are formed between the guide rails 120.

The pulling member 15 is similar to L-shaped. A bent portion 151 is bent from a front end of the pulling member 15. A protruding post 153 is formed on a lower surface of the bent portion 151. A resilient tab 154 extends from the front end of the pulling member 15. The resilient tab 154 extends parallel to the front end of the pulling member 15 and the lower surface of the bent portion 151. A block 155 is formed on a free end of the resilient tab 154. The pulling member 15 defines a sliding slot 157 in a middle portion of the body thereof, and forms a pulling portion 159 on a rear end of the body thereof.

The manipulating section 17 is a quadrate block with an arcuate corner. An installing hole 171 is defined in an end of the manipulating section 17 near the arcuate corner thereof. A stopping tab 173 is formed on a corner of the manipulating section 17 corresponding to the block 155 of the pulling member 15. The manipulating section 17 includes a first flange 174 and a second flange 175 corresponding to the resilient tab 154 of the pulling member 15. The manipulating section 17 is assembled to the pulling member 15. The protruding post 153 of the pulling member 15 extends through the installing hole 171 of the manipulating section 17, and the manipulating section 17 is pivotally connected to the pulling member 15. When the manipulating section 17 is in the first state, the resilient tab 154 of the pulling member 15 is bending and presses the first flange 174 of the manipulating section 17, and the manipulating section 17 is retained between the resilient tab 154 and the protruding post 153 of the pulling member 15. When the manipulating section 17 is pivoted to the second state, the block 155 of the pulling member 15 stops the stopping tab 173 of the manipulating section 17 from being overpivoted. The resilient tab 154 of the pulling member 15 is bending and presses the second flange 175 of the manipulating section 17, and the manipulating section 17 is retained between the resilient tab 154 and the protruding post 153 of the pulling member 15.

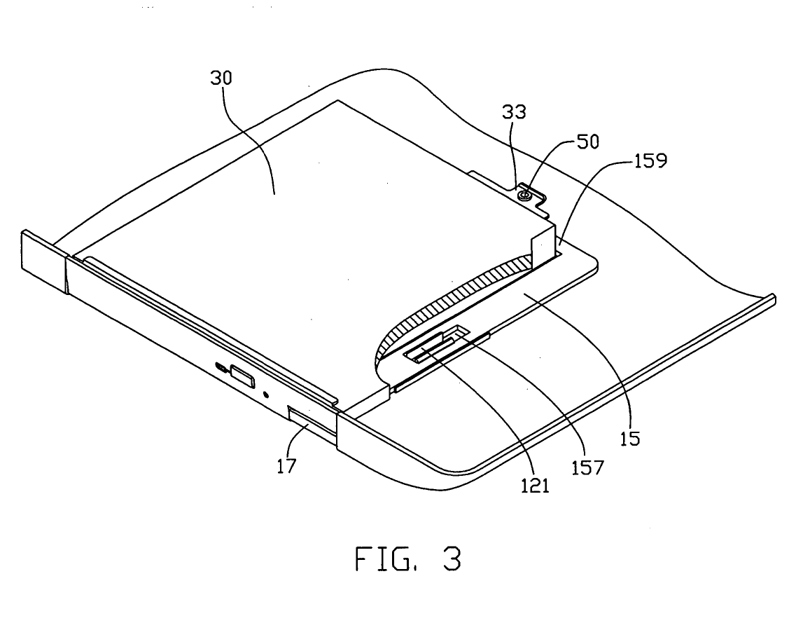

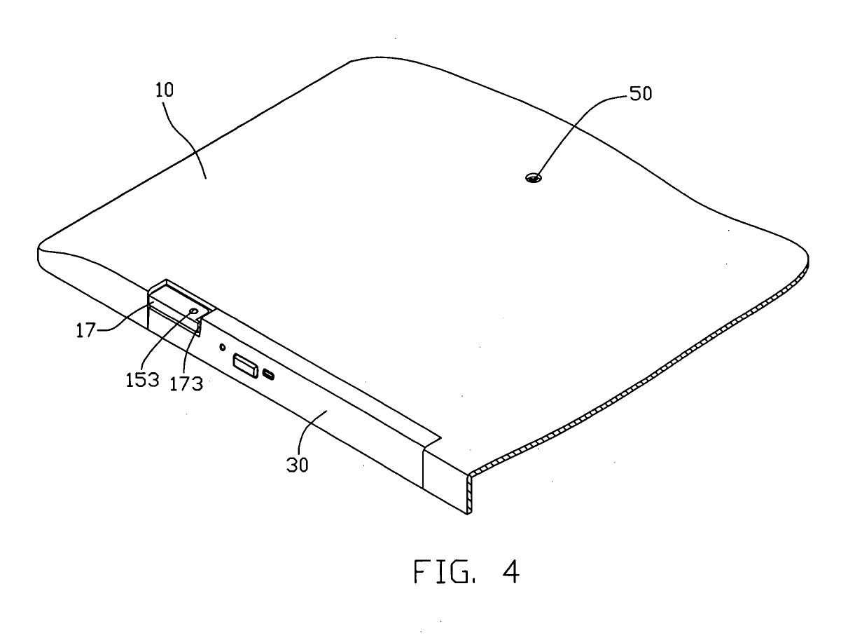

Referring also to FIGS. 3 and 4, in assembling the pulling assembly, the protruding post 153 of the pulling member 15 extends through the installing hole 171 of the manipulating section 17, and the manipulating section 17 is pivotally connected to the pulling member 15. The clasps 121 of the installing portion 12 extend through the sliding slot 157 of the pulling member 15, and engage with the edges of the sliding slot 157. Thus, the pulling member 15 is arranged in the inner side of the bottom panel 11, and can slide along the guide rails 120. The manipulating section 17 is arranged in an outer side of the bottom panel 11. The fixing plate 33 is mounted to the rear wall 31 of the electronic module 30 by the screws 35. The electronic module 30 is pulled into the notebook computer enclosure 10 from the opening 111. The connector 310 connects with a connector of a motherboard in the notebook computer enclosure 10. The screw 50 extends through the round hole 116 of the positioning post 115 then engages in the securing hole 335 of the fixing plate 33, thus the electronic module 30 is attached to the notebook computer enclosure 10. The pulling portion 159 of the pulling member 15 abuts against the rear wall 31 of the electronic module 30, and the manipulating section 17 is in the first state.

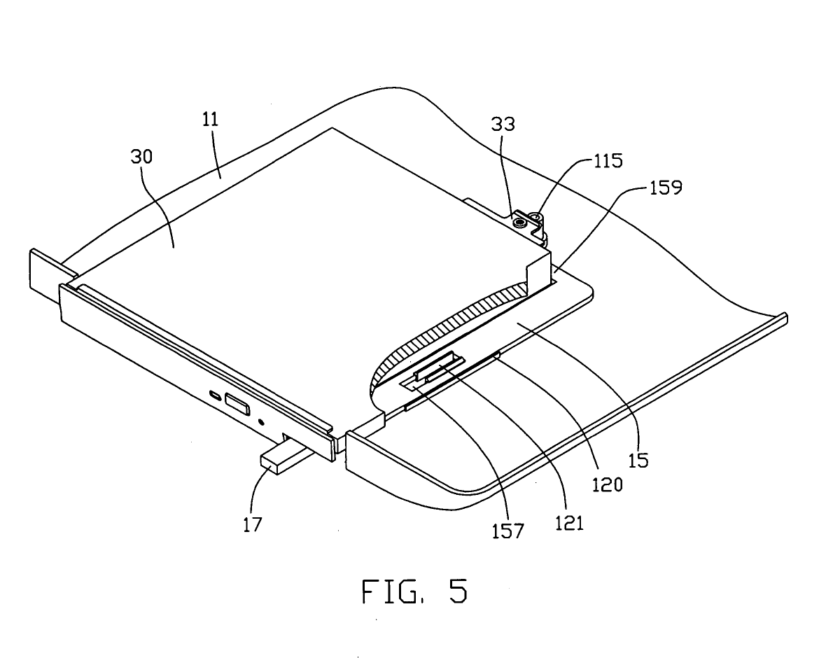

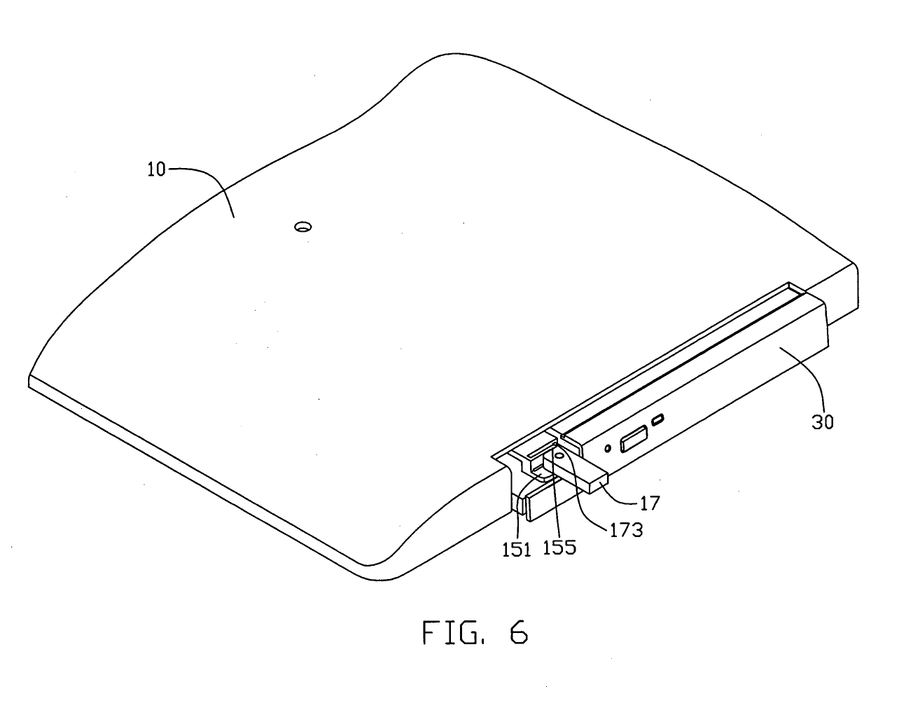

Referring also to FIGS. 5 and 6, in detaching the electronic module 30, the screw 50 is unscrewed from the securing hole 335 of the fixing plate 33. The manipulating section 17 is pivoted to the second state. Then the manipulating section 17 is pulled forward, and the pulling member 15 is driven by the manipulating section 17 to slide along the guide rails 120. The pulling member 15 pulls the electronic module 30 forward along the sliding rails 113. Therefore, the connector 310 is pulled out and the electronic module 30 is pulled out a certain distance to facilitate being taken out from the notebook computer enclosure 10.

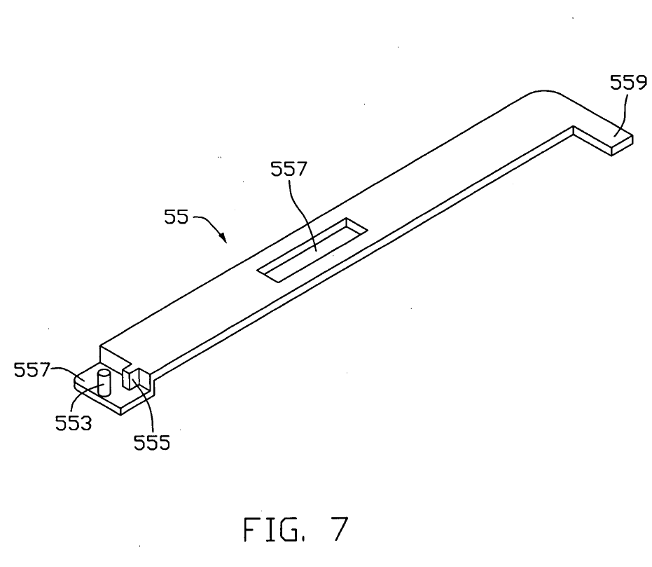

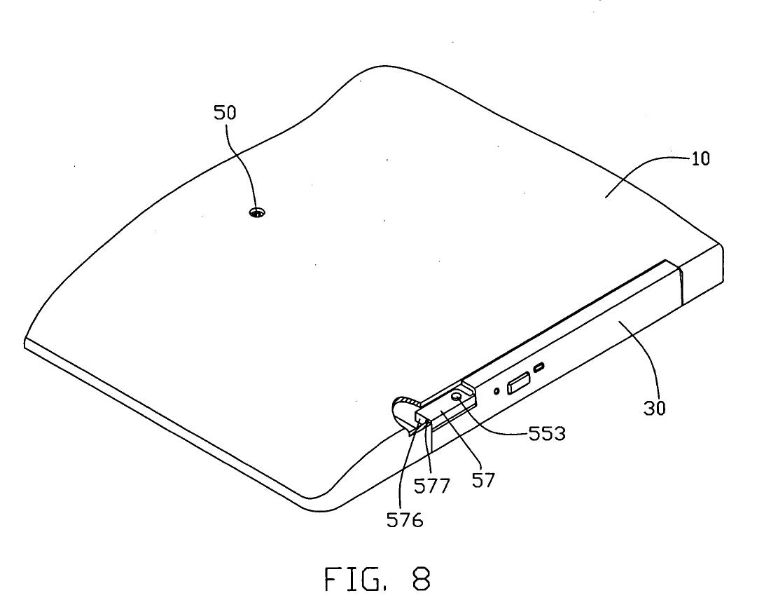

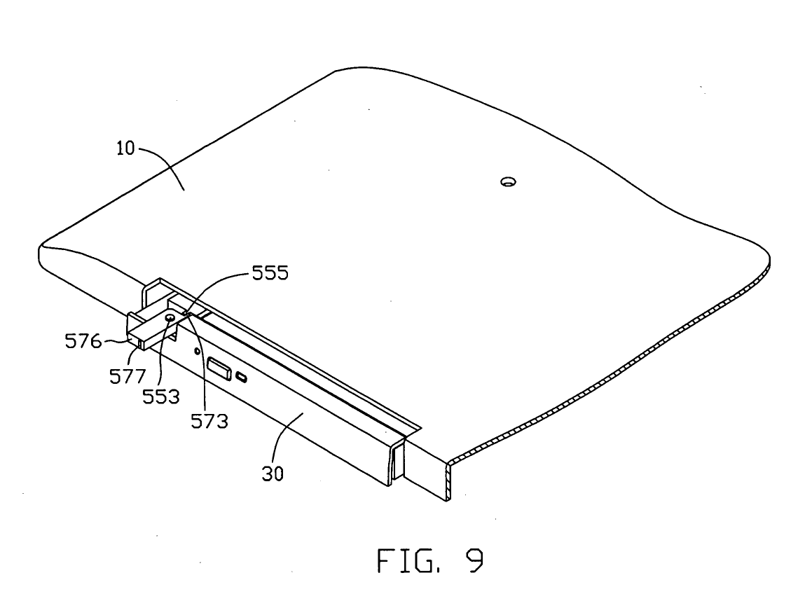

Referring to FIGS. 7 to 9, a second embodiment of the present invention is described. In this embodiment, the components of the pulling assembly are same as the first embodiment except the pulling member 55 and the manipulating section 57.

The pulling member 55 is similar to the pulling member 15 of the first embodiment, but the resilient tab 154 and the block 155 of the pulling member 15 are canceled. Instead, a block 555 is formed on a front end of the pulling member 55. The protruding post 553 of the bent portion 551 is longer than the protruding post 153 of the pulling member 15. The pulling member 55 includes a sliding slot 557 and a pulling portion 559.

The manipulating section 57 includes an installing hole and a stopping tab 573. The installing hole and the stopping tab 573 are same as the installing hole 171 and the stopping tab 173 of the manipulating section 17 respectively. A protrusion 577 is formed on a flange 576 of the manipulating section 57.

In assembling the pulling assembly, the protruding post 553 of the pulling member 55 extends through the installing hole of the manipulating section 57, and a free end of the protruding post 553 is melted to retain the manipulating section 57. Thus, the manipulating section 57 is pivotally connected to the pulling member 55. The pulling member 15 is arranged in the inner side of the bottom panel 11, and the electronic module 30 is attached to the notebook computer enclosure 10. The pulling portion 559 of the pulling member 55 abuts against the rear wall 31 of the electronic module 30. An inner surface of the side panel 11 of the notebook computer enclosure 10 abuts against the protrusion 577 to keep the manipulating section 57 in the first state.

In detaching the electronic module 30, the screw 50 is unscrewed, and the manipulating section 57 is pivoted to the second state. The block 555 of the pulling member 55 stops the stopping tab 573 of the manipulating section 57 from being overpivoted. Then the manipulating section 57 is pulled forward to pull out the connector 310, and the electronic module 30 is pulled out a certain distance to facilitate being taken out from the notebook computer enclosure 10.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

We claim:

1. A pulling assembly for pulling an electronic module out of a computer enclosure, the pulling assembly comprising:
an installing portion formed on the computer enclosure;
a pulling member slidably arranged in the computer enclosure by the installing portion, the pulling member pulling the electronic module to slide a certain distance to facilitate the electronic module being taken out from the computer enclosure; and
a manipulating section pivotally connected to the pulling member, and the manipulating section driving the pulling member to slide along the installing portion.

2. The pulling assembly as claimed in claim 1, wherein the electronic module comprises a rear wall, and a pulling portion of the pulling member abuts against and pulls the rear wall to slide the electronic module.

3. The pulling assembly as claimed in claim 1, wherein the installing portion comprises a pair of clasps, the pulling member defines a sliding slot, the clasps extend through the sliding slot, and engage with the edges of the sliding slot, thus the pulling member is slidably arranged in the computer enclosure.

4. The pulling assembly as claimed in claim 1, wherein a bent portion is bent from an end of the pulling member, a protruding post is formed on the bent portion, an installing hole is defined in an end of the manipulating section, the protruding post of the pulling member extends through the installing hole of the manipulating section, and the manipulating section is pivotally connected to the pulling member.

5. The pulling assembly as claimed in claim 4, wherein a resilient tab extends from the end of the pulling member, the manipulating section comprises a first flange and a second flange, the resilient tab presses the first flange or the second flange to retain the manipulating section at a first state or a second state.

6. The pulling assembly as claimed in claim 4, wherein a protrusion is formed on a flange of the manipulating section, an inner surface of the computer enclosure abuts against the protrusion to keep the manipulating section in a certain state.

7. The pulling assembly as claimed in claim 4, wherein a block is formed on the pulling member, a stopping tab is formed on the manipulating section, and the block of the pulling member stops the stopping tab of the manipulating section from being overpivoted.

8. The pulling assembly as claimed in claim 1, wherein installing portion comprises a pair of guide rails, the guide rails run parallel to each other, and the pulling member slides along the guide rails.

9. A pulling assembly for pulling an electronic module out of an enclosure of an electronic device without opening the enclosure, the pulling assembly comprising:
an installing portion formed on an inner side of the enclosure;
a pulling member slidably arranged in the enclosure by the installing portion, a pulling portion formed on the pulling member, and the pulling portion abutting against and pulling the electronic module sliding a certain distance to facilitate the electronic module being taken out from the enclosure; and
a manipulating section pivotally assembled to the pulling member and arranged in an outer side of the enclosure, and the manipulating section driving the pulling member to move along a first direction in which the electronic module moves.

10. The pulling assembly as claimed in claim 9, wherein the pulling portion extends from the pulling member in a second direction perpendicular to the first direction to pull a rear wall of the electronic module.

11. The pulling assembly as claimed in claim 10, wherein the installing portion comprises a pair of clasps, the pulling member defines a sliding slot, the clasps extend through the sliding slot, and engage with the edges of the sliding slot, thus the pulling member is slidably arranged in the enclosure.

12. The pulling assembly as claimed in claim 9, wherein a bent portion is bent from an end of the pulling member, a protruding post is formed on the bent portion, an installing hole is defined in an end of the manipulating section, the protruding post of the pulling member extends through the installing hole of the manipulating section, and the manipulating section is pivotally connected to the pulling member.

13. The pulling assembly as claimed in claim 12, wherein a resilient tab extends from the end of the pulling member, the manipulating section comprises a first flange and a second flange, the resilient tab presses the first flange or the second flange to retain the manipulating section at a first state or a second state.

14. The pulling assembly as claimed in claim 12, wherein a protrusion is formed on a flange of the manipulating section, an inner surface of the enclosure abuts against the protrusion to keep the manipulating section in a certain state.

15. The pulling assembly as claimed in claim 12, wherein a block is formed on the pulling member, a stopping tab is formed on the manipulating section, and the block of the pulling member stops the stopping tab of the manipulating section from being overpivoted.

16. The pulling assembly as claimed in claim 9, wherein the electronic module comprises a connector at a rear wall thereof to connect with the electronic device.

17. An electronic device comprising:
an enclosure of said electronic device enclosing said electronic device and defining a space therein, an opening definable along a side of said enclosure to allow said space of said enclosure spatially communicable with an outside of said enclosure;
an electronic module removably installable in said space of said enclosure by means of moving through said opening along a first direction, and functioning for said electronic device after installation thereof;
a pulling member installably extending along a side of said space in said enclosure, and being engagable with said installed electronic module in said space to urge said electronic module to move toward said outside of said enclosure through said opening by means of operably moving along a second direction opposite to said first position, said pulling member being engagable with an installing portion formed from said enclosure beside said space so as to be retainable beside said space and guidably movable along said second direction.

18. The electronic device as claimed in claim 17, wherein said installing portion comprises at least one guide rail to guide movement of said pulling member along said second direction, and at least one clasp protrusively extending through said pulling member to retain said pulling member beside said space of said enclosure.

19. The electronic device as claimed in claim 17, further comprising a manipulating section movably connectable with said pulling member and exposable to said outside of said enclosure in order to provide a user controllable access to said pulling member, said manipulating section is movable relative to said pulling member between a first position thereof where said manipulating section is exposably flush with an outline of said enclosure beside said opening and is not user-operable to control said pulling member, and a second position thereof where said manipulating section is exposably protrusive into said outside of said enclosure to allow user operation thereon in order for controlling said pulling member.
